(19) United States
(12) Patent Application Publication
(10) Pub. No.: US 2010/0140686 A1
(43) Pub. Date: Jun. 10, 2010

(54) FLASH MEMORY AND METHOD OF MANUFACTURING A FLASH MEMORY

(75) Inventor: Daisuke Arizono, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/635,324

(22) Filed: Dec. 10, 2009

(30) Foreign Application Priority Data
Dec. 10, 2008 (JP) P2008-314288

(51) Int. Cl. H01L 29/792; H01L 21/336

(52) U.S. Cl. 257/324; 438/261; 257/E29.309; 257/E21.409

(57) ABSTRACT

A semiconductor memory which includes a semiconductor substrate, a plurality of memory cells, and a plurality of active regions disposed in the substrate between adjacent ones of the memory cells. At least two contact electrodes are disposed between adjacent ones of the memory cells and each being connected to one of the active regions, and a contact member is connected to one of the contact electrodes and extending over a gate electrode of a memory cell disposed adjacent to the one contact electrode. Faults can be detected in the memory cells due to particles located between the various insulator and electrode layers in the gate electrode structure, or between the substrate and the gate insulator of the memory cell.

### CROSS REFERENCE TO THE RELATED APPLICATION

This application is based upon and claims the benefit of priority from the prior Japanese Application No. 2008-314288, filed Dec. 10, 2008, the entire contents of which are incorporated herein by reference.

### FIELD OF THE INVENTION

The present invention relates to a flash memory and a method of manufacturing the flash memory.

### BACKGROUND OF THE INVENTION

There has been a NOR-type flash memory having ETOX-type (EPROM Thin Oxide-type) memory cell transistor. This memory cell transistor uses a hot electron effect for writing data, and uses a Fowler-Nordheim tunneling current for data erasing. Please refer to Japanese Patent Publication (Kokai) No. 2006-303009.

If there is any particle, such as dust, between a semiconductor substrate and a gate electrode, or in the gate electrode, the memory cell transistor of this flash memory is likely not able to read, write, and erase any data. However, in the case of smaller dust, the memory cell transistor of this flash memory is able to read, write, and erase any data at an early stage. This memory cell transistor will be referred to as “the memory cell transistor that has a potential bug”. When data is written and erased over and over again, “the memory cell transistor that has a potential bug” is not able to operate any more.

Screening for “the memory cell transistor that has a potential bug” can be performed by writing and erasing data over and over again preliminarily, but this screening is impractical because of time and cost. Screening for “the memory cell transistor that has a potential bug” has not been adopted.

### SUMMARY OF THE INVENTION

The present invention may provide a flash memory that is able to screen a memory cell transistor having an abnormal structure, for example “the memory cell transistor that has a potential bug”, and provide a method of manufacturing this flash memory.

According to one aspect of the present invention, this flash memory is provided, which comprises a semiconductor substrate, such as silicon, a normal gate electrode having a flat upper surface, an abnormal gate electrode having an upper surface with a projection. The normal gate electrode is separated from a via that contains a first contact electrode connecting a first diffused layer and a bit line. The abnormal gate electrode is connected with the via at the projection.

### BRIEF DESCRIPTION OF THE DRAWINGS

FIG. 1 is a cross-sectional view of a flash memory in accordance with one embodiment of the present invention;

FIG. 2 is a cross-sectional view of a flash memory, during the process for manufacturing, in accordance with one embodiment of the present invention;

FIG. 3 is a cross-sectional view of a flash memory, during the process for manufacturing, in accordance with one embodiment of the present invention;

FIG. 4 is a cross-sectional view of a flash memory, during the process for manufacturing, in accordance with one embodiment of the present invention;

FIG. 5 is a perspective plan view of FIG. 4;

FIG. 6 is a cross-sectional view of a flash memory, during the process for manufacturing, in accordance with one embodiment of the present invention;

FIG. 7 is a cross-sectional view of a flash memory, during the process for manufacturing, in accordance with one embodiment of the present invention;

FIG. 8 is a perspective plan view of FIG. 7;

FIG. 9 is a cross-sectional view of a flash memory, during the process for manufacturing, in accordance with one embodiment of the present invention;

FIG. 10 is a perspective plan view of FIG. 9; and

FIG. 11 is a flowchart of screening a flash memory in accordance with a second embodiment of the present invention.

### DETAILED DESCRIPTION OF THE INVENTION

Embodiments of the present invention will be explained in reference to the drawings as follows. The following embodiments apply the present invention to a NOR-type flash memory. However, the invention is not limited to a NOR-type flash memory but may also be applied to NAND-type flash memory.

### First Embodiment

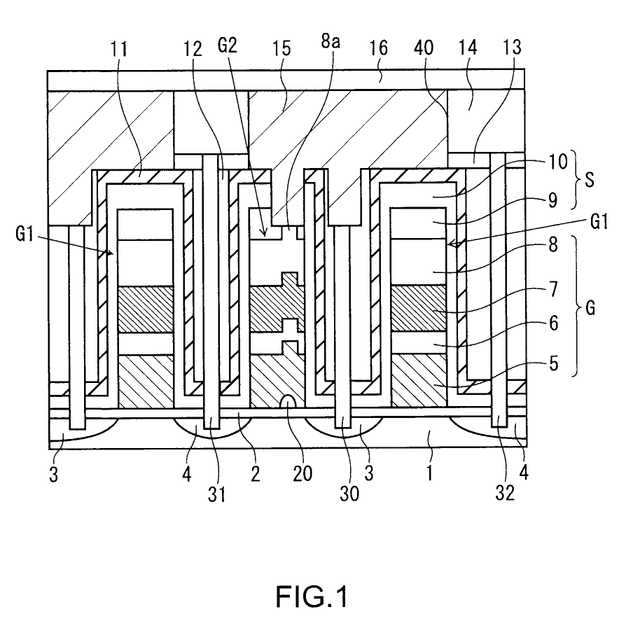

FIG. 1 is a cross-sectional view of a channel length direction showing a first embodiment.

A STI (Shallow Trench Isolation), which is not shown in the figure, is formed in a surface of substrate 1 made of, for example, silicon. The STI defines an active region. Memory cell transistors are arranged within the active region. The memory cell transistor comprises a gate electrode G formed upon the surface of silicon substrate 1 through a gate insulator 2, a first diffused layer 3 (drain) and a second diffused layer 4 (source). The first diffused layer 3 or the second diffused layer 4 is shared by the memory cell transistors laying side-by-side.

The gate electrode G comprises a floating gate 5 made of, for example, a polysilicon film, a electrode insulating film 6, a control gate 7 made of for example, a polysilicon film, and a low-resistance contact layer 8. The layer 8 can be a polycide layer made of a tungsten silicide and is formed on the control gate 7 for a reduction in resistance. A first oxide film 9 and a second oxide film 10 made of, for example, TEOS are formed on the layer 8. Oxide film 9 and 10 are collectively referred as oxide film S.

If there is a particle 20, such as dust, in the gate electrode G, for example between the gate insulator 2 and the floating gate 5, a projection 8a is formed on upper surface of the layer 8. A projection Sa is also formed on an upper surface of the oxide film S. In contrast, if there is no particle, such as dust, in the gate electrode G, the upper surfaces of the layer 8 and the oxide film S remain flat. The gate electrode G whose the upper surface is flat is referred to as a normal gate electrode G1, and the gate electrode G whose the upper surface has the projection 8a is referred to as an abnormal gate electrode G2.

If the particle 20 is 20 nm-50 nm high, the projection 8a and Sa are also 20 nm-50 nm high. The 20 nm-50 nm height is a defined value.

A nitride film 11, which is 20 nm-50 nm thick, is formed over and sheathes the normal gate electrode G1 (see right or left side of FIG. 1) and the abnormal gate electrode G2 (center of FIG. 1). The upper surface of the oxide film S is completely sheathed by the nitride film 11 at the normal gate electrode G1, but the upper surface of the projection 8a will become exposed in the abnormal gate electrode G2, as explained below. A first interlayer dielectric film 12 is formed between the normal gate electrode G1 and the abnormal gate electrode G2 having an upper surface the same height as that of the upper surface of the nitride film 11 by CMP. A second interlayer dielectric film 13 is formed upon the nitride film 11 and the first interlayer dielectric film 12.

A first contact electrode 30 is connected to the first diffused layer 3 through the first interlayer dielectric film 12. A second contact electrode 31 and a third contact electrode 32 are connected separately to the second diffused layer 4 through the first interlayer dielectric film 12 and the second interlayer dielectric film 13. A third interlayer dielectric film 14 is formed upon the second interlayer dielectric film 13 and the first, second, third contact electrodes 30, 31, 32.

A via hole 40 is formed in the second and third interlayer dielectric film 13, 14 between the second contact electrode 31 and the third contact electrode 32. The via hole 40 reaches a top edge of the first contact electrode 30 and the upper surface of the projection 8a of the unusual gate electrode G2, and also the nitride film 11 upon the normal gate electrode G1 and the abnormal gate electrode G2. The via hole 40 can also be formed to reach at least the upper surface of the gate electrode where there is no projection. A via 15, which is a metallic layer, is formed in the via hole 40. Via 15 comes into contact with more than half of the upper surface of the nitride film 11 on the normal gate electrode G1 and the abnormal gate electrode G2. Via 15 is connected to the first contact electrode 30, but does not contact the second and third contact electrodes 31, 32.

The nitride film should fulfill the following formula.

Tn≦Tf+Tc+Te Formula

“Tn” is the thickness of the nitride film. “Tf” is the height of the material (such as a particle) that exists between a semiconductor substrate and gate the electrode or in the gate electrode. “Tc” is the thickness of the nitride film removed by the planarization process. “Te” the thickness of the nitride film removed by the etching in forming the via hole.

Nitride film 11 over the projection 8a of the abnormal gate electrode G2 is removed by CMP of the first interlayer dielectric film 12. Via hole 40 is etched to reaches a top edge of the first contact electrode 30, and the upper surface of the projection 8a of the unusual gate electrode G2 is exposed by the etching, as pointed out above.

Via 15 is electrically-insulated from the normal gate electrode G1 by the nitride film 11, but is connected to projection 8a of the abnormal gate electrode G2. The abnormal gate electrode G2 is electrically-shorted to the first diffused layer 3.

A bit line 16 is formed above the third interlayer dielectric film 14 and the via 15. The bit line 16 is connected to the first diffused layer 3 through the via 15.

In the case of NAND, the exact memory cell that is abnormal cannot be identified. However, the NAND string that includes an abnormal memory cell can be identified. For redundancy, the NAND string that includes an abnormal memory cell is replaced with another NAND string. The replacement may also be done by column and block.

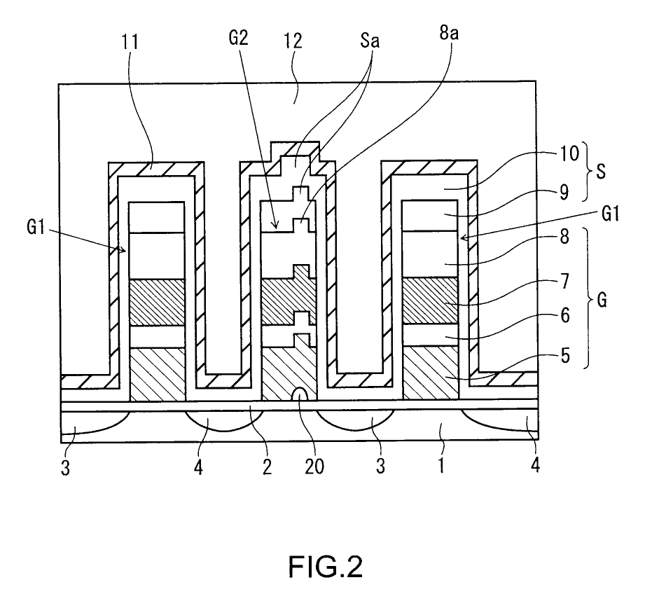

FIGS. 2, 3, 4, 6, 7 and 9 show cross-sectional views of a flash memory fabricated according to a first embodiment of a method in accordance with the present invention.

As shown in FIG. 2, the STI (not shown) is formed in the silicon substrate 1 surface, and the gate insulator 2, which is, for example, an oxide film, is formed upon the silicon substrate 1 surface. A floating gate 5 made of, for example, a polysilicon film, is formed upon the gate insulator 2.

An electrode insulating film 6, for example, an oxide film, is formed upon the floating gate 5, and a control gate 7 made of, for example, polysilicon, is formed upon the electrode insulating film 6. The low-resistance contact layer 8 made of, for example, tungsten silicide is formed on the control gate 7 for decreasing an interconnection resistance. The first oxide film 9, made of TEOS etc., is formed upon the polycide layer 8 for a mask.

A resist pattern is formed by lithography for manufacturing the gate electrode G, and the first oxide film 9 is etched using the resist pattern as a mask. Then the resist pattern is removed. The gate electrode G is formed by using the first oxide film 9 as a mask and etching the polycide layer 8, the control gate 7, the electrode insulating film 6, and the floating gate 5.

For example, if there is a particle 20 between the gate insulator 2 and the floating gate 5, the projection 8a is formed and the gate electrode G becomes the abnormal gate electrode G2. Finally, the projection Sa is formed because of the particle 20. If there is no particle 20, the gate electrode G becomes the normal gate electrode G1 which has a flat upper surface.

The second oxide film 10 is formed around the gate electrode G to sheath oxide film S.

Impurity ions are injected in the silicon substrate 1 between the each gate electrodes G. The impurity ions are annealed, forming the first diffused layer 3 (drain) and the second diffused layer 4 (source).

For the purpose of protecting the memory cell transistor, the nitride film 11 whose film thickness is about 20 nm-50 nm is formed over the normal gate electrode G1 and the abnormal gate electrode G2. The first interlayer dielectric film 12 is formed upon the nitride film 11.

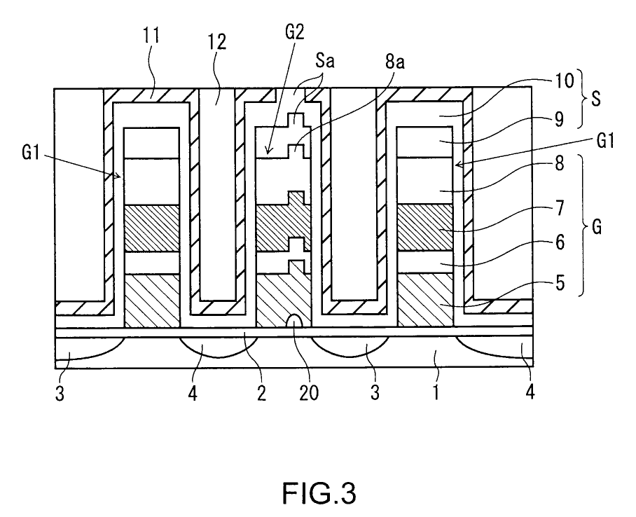

As showing in FIG. 3, the nitride film 11 of the normal gate electrode G1 of about 5 nm-15 nm is removed by CMP. By CMP of the nitride film 11 under this condition, the nitride film 11 of the abnormal gate electrode G2 above the upper surface of the projection 8a is completely removed, and the projection Sa is exposed.

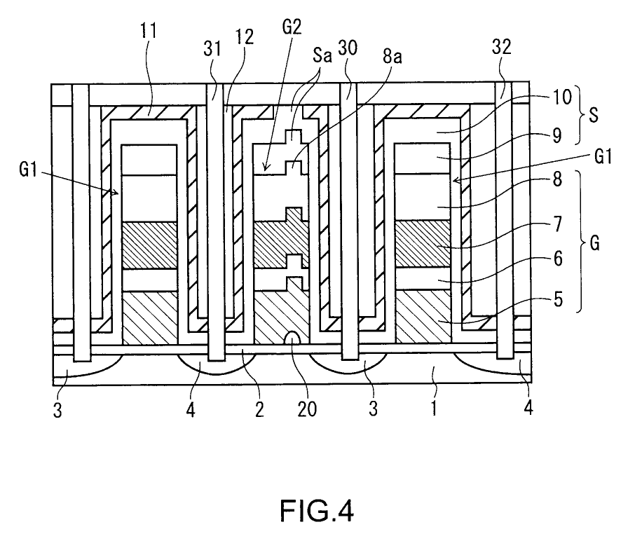

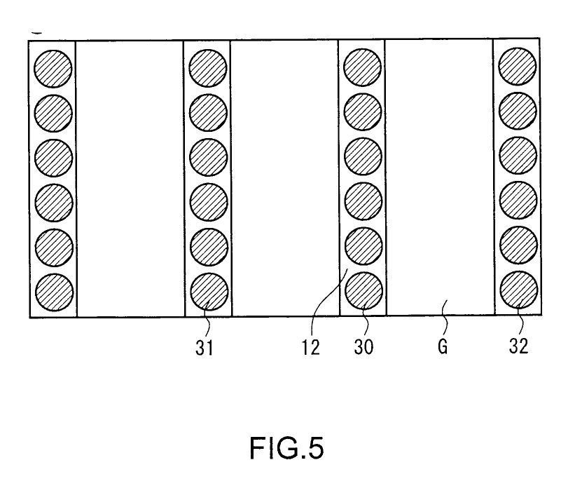

As shown in FIGS. 4 and 5, the second interlayer dielectric film 13, made of D-TEOS etc., for example, is formed upon the nitride film 11 and the first interlayer dielectric film 12. The resist pattern for manufacturing the first, second, third contact electrodes 30, 31, 32 is formed by lithography, and contact holes connected to the first diffused layer 3 (drain) and the second diffused layer 4 (source) are formed by using the resist pattern as a mask. The first, second, third contact electrodes 30, 31, 32 are formed by embedding conductive material, for example tungsten, in the contact holes.

FIG. 5 is a planar view of the structure shown in FIG. 4 with contact electrodes 30, 31 and 32 arranged in rows and formed in interlayer dielectric film 12. Film 13 is formed between the rows. Contact electrodes 30, 31 and 32 are shown as circular in shape, but other shapes are possible, for example, an oval or quadrangular shape.

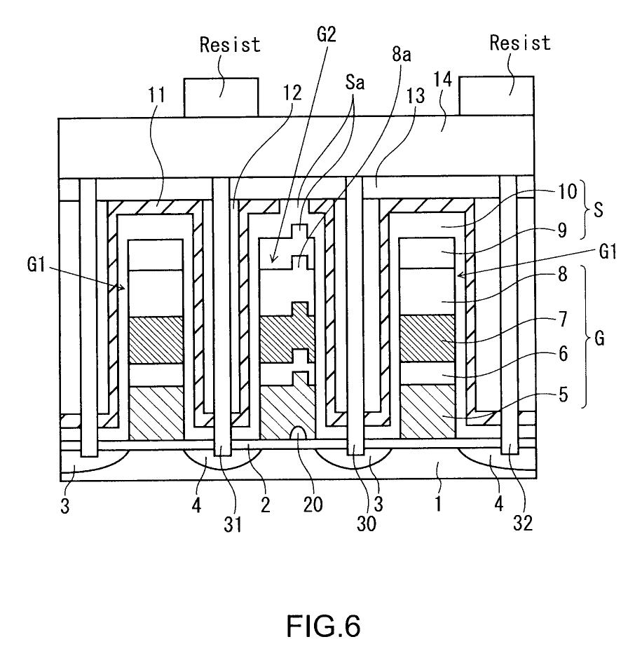

As shown in FIG. 6, the third interlayer dielectric film 14, made of D-TEOS etc., for example, is formed upon the second interlayer dielectric film 13, and the first, second, third contact electrodes 30, 31, 32.

A resist pattern, which exposes the third interlayer dielectric film 14 above two gate electrodes and the first contact electrode 30, is formed between the second and third contact electrodes 31, 32 by lithography.

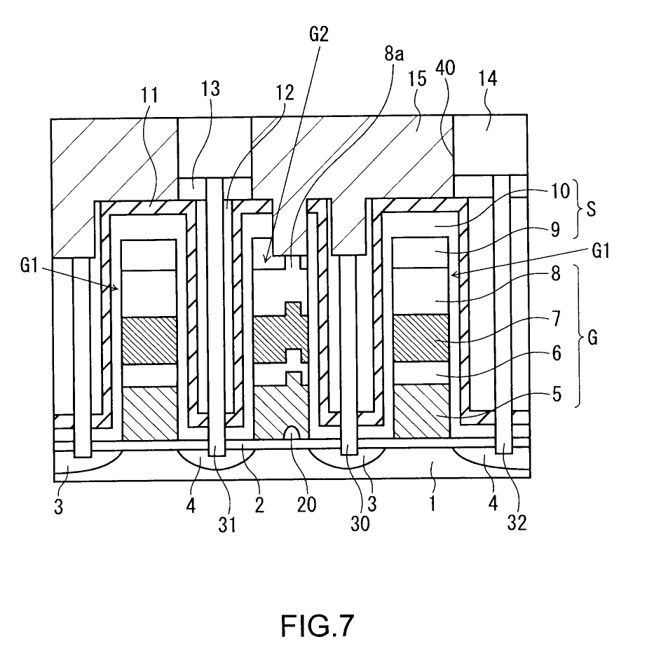

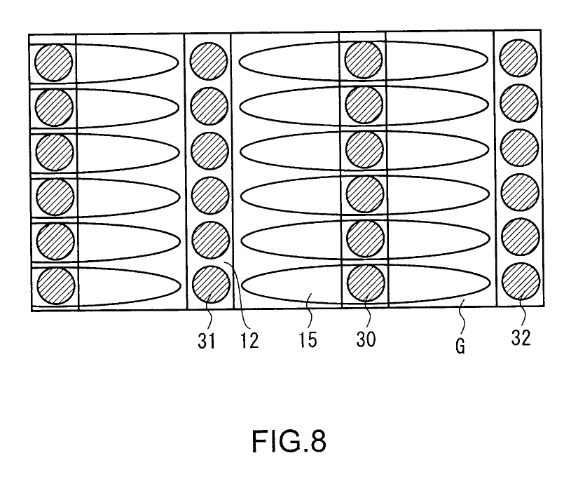

As shown in FIGS. 7 and 8, the via hole 40 is formed by etching the third interlayer dielectric film 14 using the resist pattern as a mask.

The conditions of the etching of the via hole 40 are selected such that an etching rate of an oxide film is faster than an etching rate of a nitride film, and the etching time is long enough to remove the third interlayer dielectric film 14, the second interlayer dielectric film 13, and the oxide film S. The etching also removes a portion of contact electrode 30.

The upper surface of the projection 8a of the abnormal gate electrode G2 is exposed because the nitride film 11 over projection Sa is removed by the CMP and the projection Sa is removed by the etching of via hole 40. But the normal gate electrode G1 is protected by the nitride film 11 after the etching for the via hole 40, and not exposed. The etching can also be continued to reach at least the upper surface of the gate electrode where there is no projection.

FIG. 8 is a planar view of the structure shown in FIG. 7 with vias 15 formed in connection with contact electrodes 30, 31 and 32. Vias 15 are shown to have an oval shape, but other shapes are possible, for example, a quadrangular shape. Also, contact electrodes 30 and portions of oxide 12, although they are located beneath vias 15, are shown for illustrative purposes.

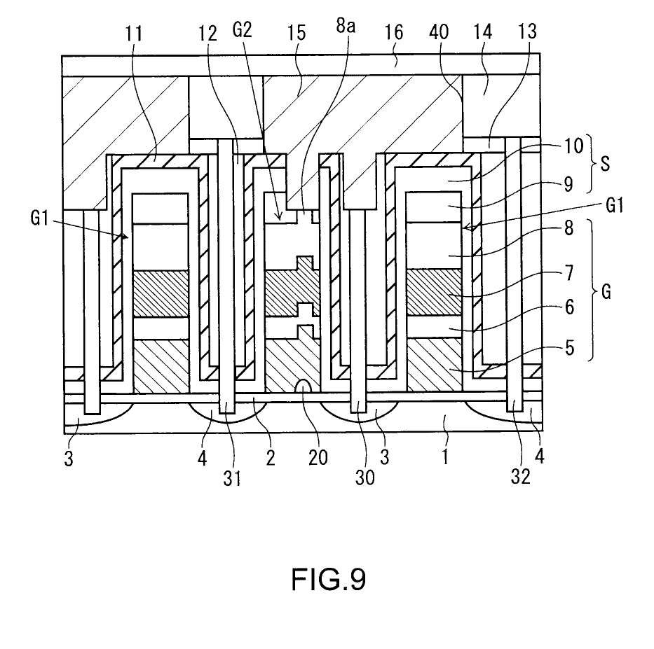

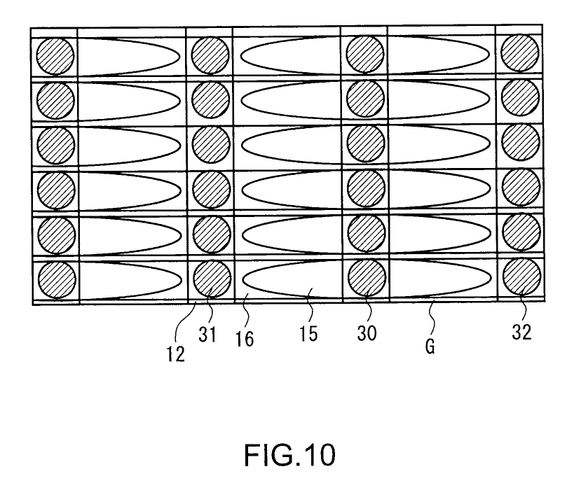

As shown in FIGS. 9 and 10, the via 15 is formed by embedding the metallic layer in the via hole 40, and the bit line 16 is formed on the via 15. FIG. 10 shows a planar view of the structure of FIG. 9, including bit line 16. Again, contact electrodes 30, 31 and 32, portions of oxide 12 and vias 15, although they are located beneath bit line 16, are shown for illustrative purposes.

With the first embodiment, the abnormal gate electrode G2 could be more easily screened by applying different voltages to the first contact electrode 30 and the gate electrode G and detecting shorts due to the abnormal gate electrode G2.

### Second Embodiment

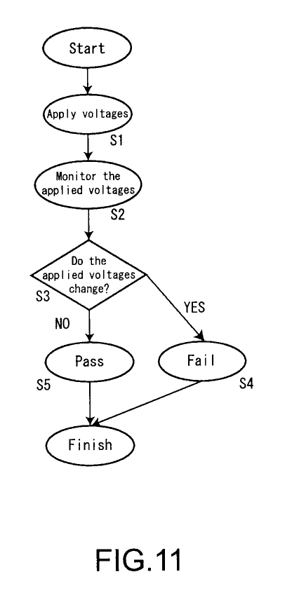

A second embodiment in accordance with the invention will be explained with reference to FIG. 11. The second embodiment shows a method for screening abnormal gate electrodes, which is a faulty memory cell transistor.

In a first step S1, a voltage, for example Vdd or 0-1.8V, is applied to the first contact electrode 30 and a different voltage, for example 10V, is applied to the gate electrode G. In a second step S2, the applied voltages are monitored. In a third step S3, changes in either of the applied voltages are evaluated by a test circuit on the same chip. In a fourth step S4, a faulty memory cell transistor is identified if the either of the applied voltages is changed. A current flows between the first contact electrode 30 and the gate electrode G, because the gate electrode G is electrically-shorted to a diffused layer. In a fifth step S5, a normal memory cell transistor is identified, if the applied voltages do not change. A current does not flow. The process of the screening is completed after checking all of the cell transistors.

Any identified faulty memory cell transistor may be replaced by a normal memory cell transistor by a redundant cell transistor, or the faulty memory cell transistor address can be indicated as not available for writing. For example, first, the bit line, which is connected to the identified faulty memory cell transistor, redundancy is done, and second, a block unit redundancy is also done.

All blocks, which are connected a bit line that is connected a faulty memory cell, are rendered defective. So that the bit line redundancy must be done first, and other blocks must be used that are not connected to the bit line. Also, all memory cell transistors, which are connected a word line that is connected a faulty memory cell, is rendered defective.

This invention is able to apply to any case where there is a particle 20, such as dust, between the silicon substrate 1 and the gate electrode G or that there is a particle 20 in the gate electrode G. This invention is also applicable to the case where a particle 20 is present in other films at other locations within the gate structure. For example, when there is a particle between the floating gate 5 and the electrode insulating film 6, between the electrode insulating film 6 and the control gate 7, or between the control gate 7 and the polycide layer 8, between the polycide layer 8 and first oxide film 9, between the first oxide film 9 and the second oxide film 10, or between second oxide film 10 and nitride film 11, as well as when there is a particle in electrode insulating film 6, control gate 7, polycide layer 8, first oxide film 9, second oxide film 10, or nitride film 11. In addition, this invention is also applicable to other memories having a multi-layered gate structure, such a NAND-type flash memory.

Numerous modifications and variations of the present invention are possible in light of the above teachings. It is therefore to be understood that, within the scope of the appended claims, the present invention can be practiced in a manner other than as specifically described herein.

What is claimed is:

1. A semiconductor memory comprising:
a semiconductor substrate;
a plurality of memory cells arranged in a first direction, the memory cell having a first insulating layer disposed on the substrate, a first gate electrode disposed over the insulating layer, and a second insulating layer disposed over upper and side surfaces of the gate electrode;
a plurality of active regions disposed in the substrate between adjacent ones of the memory cells;
at least two contact electrodes each being disposed between adjacent ones of the memory cells and each being connected to one of the active regions; and
a contact member connected to one of the contact electrodes and extending over a gate electrode of a memory cell disposed adjacent to the one contact electrode, the contact member connected a top surface of the second insulating layer.

2. The memory according to claim 1, comprising a second gate electrode disposed on the first insulating layer, a third insulating layer disposed on the second gate electrode, and the first gate electrode disposed on the third insulating layer.

3. The memory according to claim 1, wherein the contact member extends between at least midpoints in a channel direction of adjacent memory cells.

4. The memory according to claim 1, comprising:
the contact electrode having a first width in a direction perpendicular to a channel direction; and
the contact member having a second width in the channel direction substantially equal the first width.

5. The memory according to claim 1, wherein the second insulating layer is disposed on top of the first gate electrode is 20-50 nm thick.

6. The memory according to claim 1, wherein the second insulating layer is a nitride layer.

7. The memory according to claim 1, wherein only one of the memory cells is disposed between adjacent ones of the at least two contact electrodes.

8. The memory according to claim 1, wherein at least two of the memory cells are disposed between adjacent ones of the at least two contact electrodes.

9. The memory according to claim 1, wherein the memory is a flash memory.

10. The memory according to claim 1, comprising the contact member connected to the gate electrode adjacent to the one contact electrode through the second insulating layer.

11. A method of forming a semiconductor memory, comprising:
forming memory cells each having a gate insulator disposed on a semiconductor substrate, a gate electrode disposed over the gate insulator, and active regions formed in the substrate between the gate electrodes;
forming first and second contact structures each being between adjacent memory cells and connected to one of the active regions;
forming an insulating layer over the top and side surfaces of the gate electrodes; and
forming a contact member connected to one of the contact structures and extending over a gate electrode of a memory cell adjacent to the one contact structure, the contact member connected a top surface of the second insulating layer.

12. The method according to claim 11, comprising:
forming the contact member to be connected to the one contact structure and a gate electrode of a memory cell adjacent to the one contact structure.

13. The method according to claim 11, comprising:
forming the memory cells to have a floating gate electrode disposed on the gate insulator, a second gate insulator disposed on the floating gate electrode, and the gate electrode disposed on the second gate insulator;
forming an insulating material between the memory cells;
forming a trench in the insulating material;
forming each of the contact structures in a respective trench;
etching the insulating material and contact structures to form a second trench between the memory cells; and
forming the contact member in the second trench.

14. The method according to claim 13, wherein the etching further comprises forming a third trench exposing the gate electrode.

15. The method according to claim 14, comprising:
forming the memory cell to have a particle located one of between the substrate and the gate insulator, between the gate insulator and the floating gate electrode, between the floating gate electrode and the second gate insulator, and between the second gate insulator and the gate electrode;
planarizing the insulating layer; and
forming the insulating layer to have a thickness T≦Tf+Tc+Te, where:
Tf is a height of the particle,
Tc is a thickness of the insulating layer removed during the planarization, and
Te is a thickness of the insulating layer removed during etching the insulating material.

16. The method according to claim 11, comprising forming the insulating layer to be 20-50 nm.

17. The method according to claim 11, comprising forming only one of the memory cells between adjacent ones of the at least two contact electrodes.

18. The method according to claim 11, comprising forming at least two of the memory cells between adjacent ones of the at least two contact electrodes.

19. The method according to claim 11, comprising forming the contact member to extend between at least midpoints in a channel direction of adjacent memory cells.

20. The method according to claim 11, comprising:
forming the contact electrode to have a first width in a direction perpendicular to a channel direction; and
forming the contact member to have a second width substantially equal the first width.

21. The method according to claim 11, comprising:
determining whether an electrical short is present between the gate electrode and the one contact structure.

22. The method according to claim 21, comprising, if the electrical short is present, replacing the memory cell with the gate shorted to the one contact structure with a redundant memory cell.

23. The method according to claim 21, comprising, if the electrical short is present, not allowing data to be stored in the memory cell with the gate shorted to the one contact structure.
